(19) United States
(12) Patent Application Publication
(10) Pub. No.: US 2025/0071901 A1
(43) Pub. Date: Feb. 27, 2025

(54) FLEXIBLE PRINTED CIRCUIT AND DISPLAY DEVICE

(71) Applicant: KUNSHAN GO-VISIONOX OPTO-ELECTRONICS CO., LTD., Kunshan (CN)

(72) Inventors: Ke LI, Kunshan (CN); Huiyun ZHU, Kunshan (CN); Jingru LU, Kunshan (CN); Huashan CHEN, Kunshan (CN); Feng WU, Kunshan (CN); Xiaohe CHEN, Kunshan (CN)

(73) Assignee: KUNSHAN GO-VISIONOX OPTO-ELECTRONICS CO., LTD., Kunshan (CN)

(21) Appl. No.: 18/945,558

(22) Filed: Nov. 13, 2024

(30) Foreign Application Priority Data
Dec. 18, 2023 (CN) 202311745230.6

(51) Int. Cl. H05K 1/11

(52) U.S. Cl. CPC H05K 1/118; H05K 2201/10128

(57) ABSTRACT

Disclosed are a flexible printed circuit and a display device. The flexible printed circuit includes a first main portion and a second main portion mutually connected. The first main portion is provided with a plurality of first connection terminals, configured to be electrically connected to a display panel. The second main portion is provided with a plurality of second connection terminals, configured to be electrically connected a printed circuit board. The first connection terminals are arranged along a first direction and the second connection terminals are arranged along a second direction. As the first direction intersects with the second direction, when the flexible display panel contracts and makes the flexible printed circuit deviate in the first direction, alignment between the second connection terminals of the flexible printed circuit and connection terminals of the printed circuit board in the second direction may not be affected.

### CROSS-REFERENCE TO RELATED APPLICATION

The present application claims priority to Chinese Patent Application No. 202311745230.6, filed on Dec. 18, 2023, which is incorporated herein by reference in its entirety.

### TECHNICAL FIELD

The present disclosure relates to the field of display technologies, and in particular, to a flexible printed circuit and a display device.

### BACKGROUND

With development of display technology, a flexible display device is listed as a next-generation display technology with a great development prospect due to advantages such as foldability, lightness, high contrast, and wide color gamut. Bonding quality between a flexible display panel and a flexible printed circuit (FPC) and bonding quality between the flexible printed circuit and a printed circuit board (PCB) are key factors to ensure normal display of the flexible display device. However, as for an existing flexible display device, a problem of poor bonding between a flexible printed circuit and a printed circuit board or a screen body is prone to occur, affecting display effect of the flexible display device.

### SUMMARY

The present disclosure discloses a flexible printed circuit and a display device to solve a problem of poor bonding between the flexible printed circuit and the printed circuit board.

In a first aspect, the present disclosure discloses a flexible printed circuit, including a first main portion and a second main portion mutually connected, where the first main portion is provided with a plurality of first connection terminals, the plurality of first connection terminals are arranged in sequence along a first direction, and the plurality of first connection terminals are configured to be electrically connected to a display panel; the second main portion is provided with a plurality of second connection terminals, the plurality of second connection terminals are arranged in sequence along a second direction, the plurality of second connection terminals are configured to be electrically connected to a printed circuit board; and the first direction intersects with the second direction.

In a second aspect, the present disclosure discloses a display device, including a display panel, a printed circuit board, and the flexible printed circuit according to the first aspect.

According to the flexible printed circuit and the display device disclosed by the present disclosure, the flexible printed circuit includes a first main portion and a second main portion mutually connected. The first main portion is provided with a plurality of first connection terminals, and the plurality of first connection terminals are configured to be electrically connected to a flexible display panel. The second main portion is provided with a plurality of second connection terminals, and the plurality of second connection terminals are configured to be electrically connected to a printed circuit board. With the plurality of first connection terminals being arranged in sequence along a first direction, the plurality of second connection terminals being arranged in sequence along a second direction, and the first direction intersecting with the second direction, when the flexible display panel contracts and drives the flexible printed circuit to deviate in the first direction, alignment between the second connection terminals of the flexible printed circuit and a connection terminal of the printed circuit board in the second direction will not be affected, thereby solving the problem of poor bonding between the flexible printed circuit and the printed circuit board.

### BRIEF DESCRIPTION OF THE DRAWINGS

To more clearly illustrate technical solutions in the embodiments or background of the present disclosure, an explanation of accompanying drawings used in the embodiments or background of the present disclosure will be provided in the following.

FIG. 1 is a schematic diagram of connection relationship between a display panel, a flexible printed circuit, and a printed circuit board.

FIG. 2 is a schematic structural diagram of a flexible printed circuit according to an embodiment of the present disclosure.

FIG. 3 is a schematic diagram of connection relationship between a display panel, a flexible printed circuit, and a printed circuit board according to an embodiment of the present disclosure.

FIG. 4 is a schematic structural diagram of another flexible printed circuit according to an embodiment of the present disclosure.

FIG. 5 is a schematic structural diagram of still another flexible printed circuit according to an embodiment of the present disclosure.

FIG. 6 is a schematic structural diagram of yet still another flexible printed circuit according to an embodiment of the present disclosure.

FIG. 7 is a schematic structural diagram of yet still another flexible printed circuit according to an embodiment of the present disclosure.

FIG. 8 is a schematic structural diagram of yet still another flexible printed circuit according to an embodiment of the present disclosure.

FIG. 9 is a schematic diagram of positional relationship between a display panel, a flexible printed circuit, and a printed circuit board according to an embodiment of the present disclosure.

FIG. 10 is a schematic structural diagram of a display device according to an embodiment of the present disclosure.

FIG. 11 is a schematic structural diagram of a plurality of second alignment marks according to an embodiment of the present disclosure.

FIG. 12 is a schematic structural diagram of another display device according to an embodiment of the present disclosure.

FIG. 13 is a schematic structural diagram of another display device according to an embodiment of the present disclosure.

FIG. 14 is a schematic structural diagram of another display device according to an embodiment of the present disclosure.

FIG. 15 is a schematic structural diagram of another display device according to an embodiment of the present disclosure.

FIG. 16 is a schematic structural diagram of another display device according to an embodiment of the present disclosure.

### DETAILED DESCRIPTIONS OF THE EMBODIMENTS

A clear and complete description of technical solutions in the embodiments of the present disclosure will be provided with reference to the accompanying drawings. Obviously, the described embodiments are a part of the embodiments of this specification, and not all embodiments. Based on the embodiments of the present disclosure, all other embodiments obtained by those skilled in the art without creative efforts shall fall within the protection scope of the present disclosure.

In a flexible display device, one end of a flexible printed circuit is bonded to a flexible display panel, and the other end of the flexible printed circuit is bonded to a printed circuit board. However, as for a flexible display device, especially for a medium-sized or large-sized flexible display device, a problem of poor bonding between the flexible printed circuit and the printed circuit board is prone to occur, affecting display effect of the flexible display device.

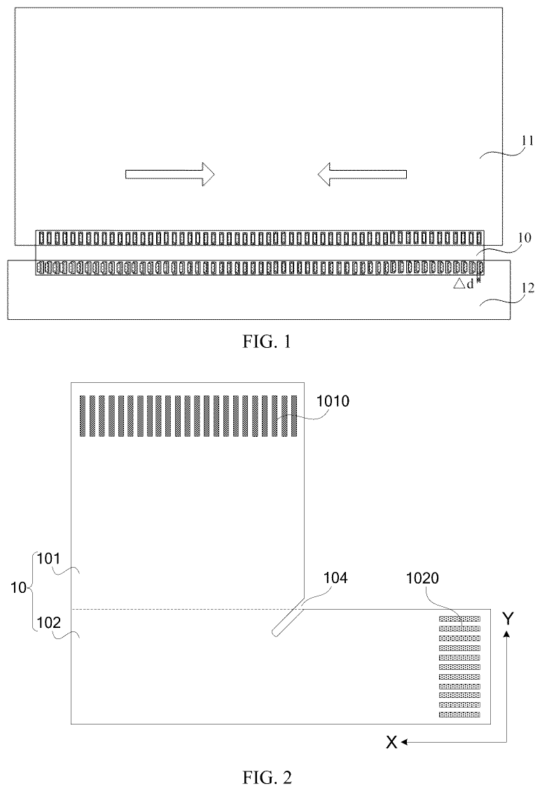

Inventor discovered that the reason for the problem mentioned above is that the flexible display panel may shrink with heat during a bonding process. FIG. 1 is a schematic diagram of connection relationship between a display panel, a flexible printed circuit, and a printed circuit board. As shown in FIG. 1, when a display panel 11 is heated, the display panel 11 will primarily shrink along a direction indicated by the arrow, which is an arrangement direction of connection terminals of the display panel 11, and the shrinkage may cause a flexible printed circuit 10 bonded to the display panel 11 to deviate in a direction of shrinkage, resulting in misalignment Δd between connection terminals of the flexible printed circuit 10 and connection terminals of a printed circuit board 12. This misalignment leads to the problem of poor bonding between the flexible printed circuit 10 and the printed circuit board 12.

By capturing shrinkage data of the display panel 11, estimating shrinkage of the display panel 11 based on the shrinkage data, and adjusting a width and spacing of the connection terminals of the flexible printed circuit 10 and the printed circuit board 12 according to the estimated shrinkage, it is possible to reduce influence of the misalignment on the bonding effect. However, repeated adjustments to the width and spacing of the connection terminals of the flexible printed circuit 10 and the printed circuit board 12 require multiple times of modifying mould for the flexible printed circuit 10 and the printed circuit board 12, resulting in high adjustment costs.

In view of this, the present disclosure discloses a flexible printed circuit. An arrangement direction of first connection terminals for electric connection between a flexible printed circuit and a flexible display panel is different from an arrangement direction of second connection terminals for electric connection between the flexible printed circuit and a printed circuit board, so that alignment between the second connection terminals of the flexible printed circuit and connection terminals of the printed circuit board will not be affected when the flexible display panel shrinks and makes the flexible printed circuit deviate along an arrangement direction of first connection terminals, thereby avoiding a bonding problem between the flexible printed circuit and the printed circuit board at a lower cost.

As an optional implementation of the present disclosure, an embodiments of the present disclosure disclose a flexible printed circuit. FIG. 2 is a schematic structural diagram of a flexible printed circuit according to an embodiment of the present disclosure. As shown in FIG. 2, the flexible printed circuit 10 includes a first main portion 101 and a second main portion 102, and the first main portion 101 and the second main portion 102 are mutually connected.

The first main portion 101 and the second main portion 102 may be integrated or separate. Dashed lines in the accompanying drawing of the present embodiment only illustrate an exemplary division of the first main portion 101 and the second main portion 102, which is not limited to this.

As shown in FIG. 2, the first main portion 101 is provided with a plurality of first connection terminals 1010, and the plurality of first connection terminals 1010 are arranged in sequence along a first direction X. The second main portion 102 is provided with a plurality of second connection terminals 1020, and the plurality of second connection terminals 1020 are arranged in sequence along a second direction Y. The first direction X intersects with the second direction Y. In some embodiments, the first direction X is perpendicular to the second direction Y. While in other embodiments, the first direction X intersects with the second direction Y but is not perpendicular to the second direction Y. For example, an angle between the first direction X and the second direction Y is configured to be any one of 30°, 60°, 120°, 150°, and so on.

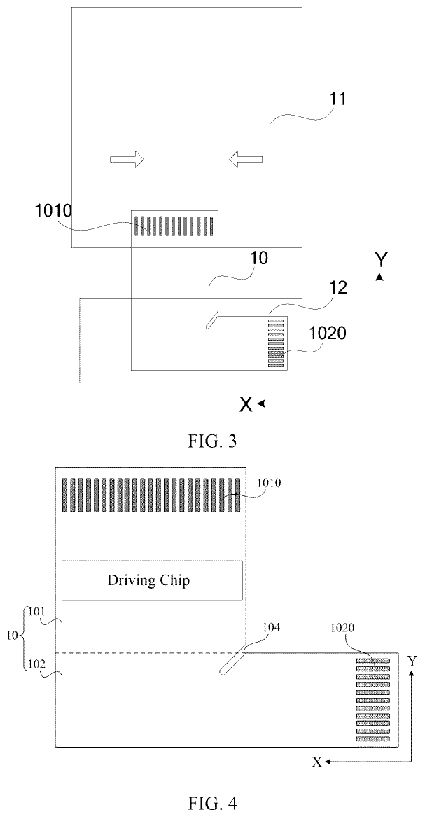

FIG. 3 is a schematic diagram of connection relationship between a display panel, a flexible printed circuit, and a printed circuit board according to an embodiment of the present disclosure. As shown in FIG. 3, a plurality of first connection terminals 1010 are configured to be electrically connected to a display panel 11. Therein, the display panel 11 may include a flexible display panel, and so on. Optionally, the display panel 11 may include a plurality of third connection terminals arranged in sequence along the first direction X, and the plurality of third connection terminals are configured to be electrically connected to the plurality of first connection terminals 1010 respectively to realize electric connection between the plurality of first connection terminals 1010 and the display panel 11, thereby achieving electric connection between the flexible printed circuit 10 and the display panel 11.

The plurality of second connection terminals 1020 are configured to be electrically connected to a printed circuit board 12. Optionally, the printed circuit board 12 may include a plurality of fourth connection terminals arranged in sequence along the second direction Y, and the plurality of fourth connection terminals are configured to be electrically connected to the plurality of second connection terminals respectively to realize electric connection between the plurality of second connection terminals 1020 and the printed circuit board 12, thereby achieving electric connection between the flexible printed circuit 10 and the printed circuit board 12.

The connection terminal mentioned in embodiments of the present disclosure may also be referred to as a pad or a pin, and so on, used for realizing electric connection between devices. A material of the connection terminal may be a conductive material such as metal or metal oxide. Moreover, an electrical signal may be transmitted from one of the plurality of second connection terminals 1020 to one of the plurality of first connection terminals 1010 corresponding to the second connection terminal 1020. The plurality of first connection terminals 1010 and the plurality of second connection terminals 1020 may be electrically connected respectively through leads or electronic components located on the flexible printed circuit 10, so that the electrical signal received by the plurality of second connection terminals 1020 from the printed circuit board 12 may be transmitted to the display panel 11 through the plurality of first connection terminals 1010. In view of this, when the display panel 11 primarily shrinks in the first direction X and makes the flexible printed circuit 10 deviate in the first direction X, although the second connection terminal 1020 may also deviate along the first direction X, the second connection terminal 1020 may not deviate along the second direction Y, or the deviation along the second direction Y is small. Therefore, alignment between the second connection terminals 1020 of the flexible printed circuit 10 and the fourth connection terminals of the printed circuit board 12 in the second direction Y will not be affected, that is, misalignment between the second connection terminals 1020 of the flexible printed circuit 10 and the fourth connection terminals of the printed circuit board 12 in the second direction Y may not occur, thereby avoiding the problem of poor bonding between the flexible printed circuit 10 and the printed circuit board 12, and further ensuring the display effect of the flexible display device.

In some embodiments of the present disclosure, FIG. 4 is a schematic structural diagram of another flexible printed circuit according to an embodiment of the present disclosure. As shown in FIG. 4, the flexible printed circuit 10 may include a driving chip. A plurality of input terminals of the driving chip are electrically connected to the plurality of second connection terminals 1020, and a plurality of output terminals of the driving chip are electrically connected to the plurality of first connection terminals 1010. An electrical signal is transmitted from the printed circuit board 12 to the driving chip by at least one of the plurality of second connection terminals 1020. After processed by the driving chip and transmitted to at least one of the plurality of first connection terminals 1010 corresponding to the at least one of the plurality of second connection terminal 1020, the electrical signal will be transmitted to the display panel 11 through the first connection terminal 1010. Of course, the present disclosure is not limited to this, in other embodiments, the flexible printed circuit 10 may not include the driving chip. The driving chip may also be provided on the display panel 11. After receiving the electrical signal transmitted from the printed circuit board 12 by the at least one of the plurality of first connection terminals 1010, the driving chip will process the electrical signal and transmit the processed signal to the display panel 11.

In some embodiments of the present disclosure, as shown in FIG. 2, the first main portion 101 may include a strip-shaped structure extending along the second direction Y, and the second main portion 102 may include a strip-shaped structure extending along the first direction X. Optionally, the first direction X is perpendicular to the second direction Y, and the flexible printed circuit 10 including the first main portion 101 and the second main portion 102 is a L-shaped structure. The present disclosure is not limited to this, in other embodiments, the first direction X may intersect with the second direction Y but not be perpendicular to the second direction Y. The first main portion 101 and the second main portion 102 may also extend in other directions, and even the extension direction of the first main portion 101 may be parallel to the extension direction of the second main portion 102. Alternatively, the first main portion 101 and the second main portion 102 may be structures of other shapes.

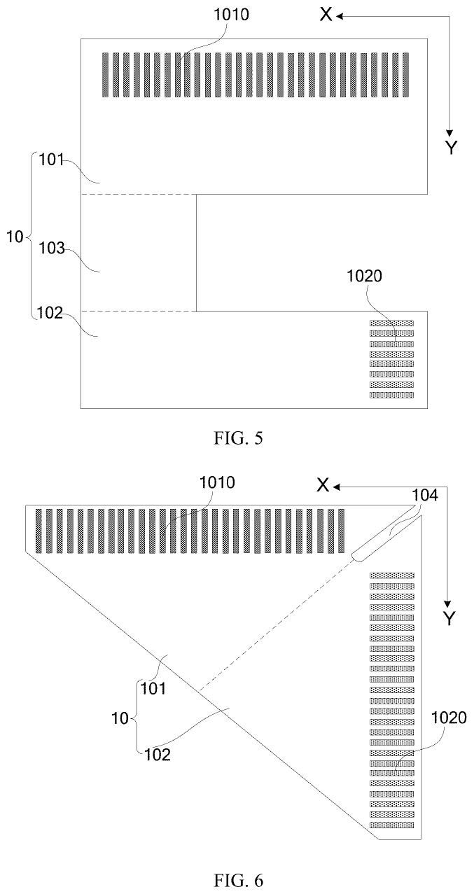

In other embodiments, FIG. 5 is a schematic structural diagram of still another flexible printed circuit according to an embodiment of the present disclosure. As shown in FIG. 5, an extension direction of the first main portion 101 is parallel to an extension direction of the second main portion 102, and the flexible printed circuit 10 including the first main portion 101 and the second main portion 102 is a U-shaped structure. In other embodiments, FIG. 6 is a schematic structural diagram of yet still another flexible printed circuit according to an embodiment of the present disclosure. As shown in FIG. 6, the first main portion 101 and the second main portion 102 are both triangular structures, and the flexible printed circuit 10 including the first main portion 101 and the second main portion 102 is also a triangular structure. In other embodiments, the first main portion 101 and the second main portion 102 may also form a trapezoidal flexible printed circuit 10.

In some embodiments of the present disclosure, the plurality of first connection terminals 1010 extend along a third direction, the plurality of second connection terminals 1020 extend along a fourth direction. Therein, the third direction intersects with the first direction X, and the fourth direction intersects with the second direction Y. In some embodiments, as shown in FIG. 2, the third direction is parallel to the second direction Y, and the fourth direction is parallel to the first direction X. In other words, the first connection terminal 1010 extends along the second direction Y, the second connection terminal 1020 extends along the first direction X, and the first direction X is perpendicular to the second direction Y.

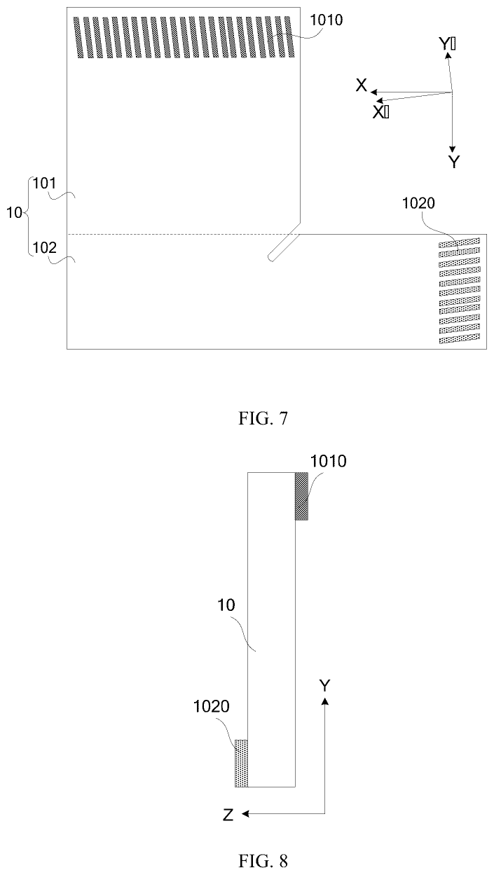

However, the present disclosure is not limited to this, in other embodiments, FIG. 7 is a schematic structural diagram of yet still another flexible printed circuit according to an embodiment of the present disclosure. As shown in FIG. 7, the plurality of first connection terminals 1010 may also extend along a third direction Y″, and the plurality of second connection terminals 1020 may extend along a fourth direction X″. The third direction Y″ intersects with the first direction X but is not perpendicular to the first direction X, and the fourth direction X″ intersects with the second direction Y but is not perpendicular to the second direction Y.

In some embodiments of the present disclosure, as shown in FIGS. 2 to 6, the first connection terminal 1010 and the second connection terminal 1020 are both strip-shaped structures. However, the present disclosure is not limited to this, in other embodiments, the first connection terminal 1010 and the second connection terminal 1020 may also be trapezoidal, triangular, circular structures, and so on, which are not described herein again. In practical applications, the shapes and/or extension directions of the first connection terminal 1010 and the second connection terminal 1020 may be configured according to requirements, as long as an arrangement direction of the first connection terminal 1010 is different from an arrangement direction of the second connection terminal 1020.

In some embodiments of the present disclosure, as shown in FIG. 5, the flexible printed circuit 10 may further include a bending portion 103. The bending portion 103 is connected between the first main portion 101 and the second main portion 102. Hardness of the bending portion 103 is less than hardness of each of the first main portion 101 and the second main portion 102, so that the first main portion 101 may be easy to bend towards or away from the second main portion 102. Optionally, a material of the bending portion 103 may be a flexible material such as silicone.

In some embodiments of the present disclosure, as shown in FIG. 7, the flexible printed circuit 10 may further include at least one slot 104. The at least one slot 104 extends from a junction of the first main portion 101 and the second main portion 102 to an interior of the flexible printed circuit 10. The junction of the first main portion 101 and the second main portion 102 may be a corner of an L-shaped structure formed by the first main portion 101 and the second main portion 102, so that stress at the junction or corner of the flexible printed circuit 10 may be reduced during bending, thereby avoiding cracking at the junction or corner of the first main portion 101 and the second main portion 102.

The slot 104 only partially extends into the interior of the flexible printed circuit 10 to prevent the slot 104 from being too large to make the first main portion 101 and the second main portion 102 disconnected. Optionally, the slot 104 is a strip-shaped slot, and an inclination angle α of the slot 104 is determined based on an angle β between the first main portion 101 and the second main portion 102. Optionally, β is 90° and α is 45°.

In the embodiment of the present disclosure, only one slot 104 is taken as an example for explanation, but the present disclosure is not limited to this, in other embodiments, the flexible printed circuit 10 may also include two, three, or even more slots 104, and the plurality of slots 104 may be located on both sides of the first main portion 101 or the second main portion 102, or at the junction of the first main portion 101 and the second main portion 102.

In some embodiments of the present disclosure, the plurality of first connection terminals 1010 and the plurality of second connection terminals 1020 may be provided on a same side of the flexible printed circuit 10. However, the present disclosure is not limited to this, in other embodiments, FIG. 8 is a schematic structural diagram of yet still another flexible printed circuit according to an embodiment of the present disclosure. As shown in FIG. 8, the plurality of first connection terminals 1010 are located on a first side of the surface of the flexible printed circuit 10, the plurality of second connection terminals 1020 are located on a second side of the surface of the flexible printed circuit 10, and the first side is opposite to the second side.

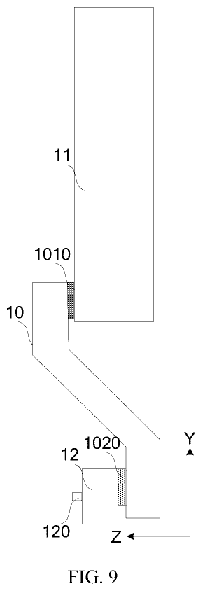

Based on this, as shown in FIG. 9, FIG. 9 is a schematic diagram of positional relationship between a display panel, a flexible printed circuit, and a printed circuit board according to an embodiment of the present disclosure. An electronic component 120 of the printed circuit board 12 and the fourth connection terminal of the printed circuit board 12 are respectively arranged on opposite surfaces, avoiding the fourth connection terminal electrically connected to the second connection terminal 1020 from affecting layout of the electronic component 120 on the printed circuit board 12. Therein, the electronic component may include, but is not limited to, a processor, a transistor, a resistor, a capacitor, and a light-emitting diode.

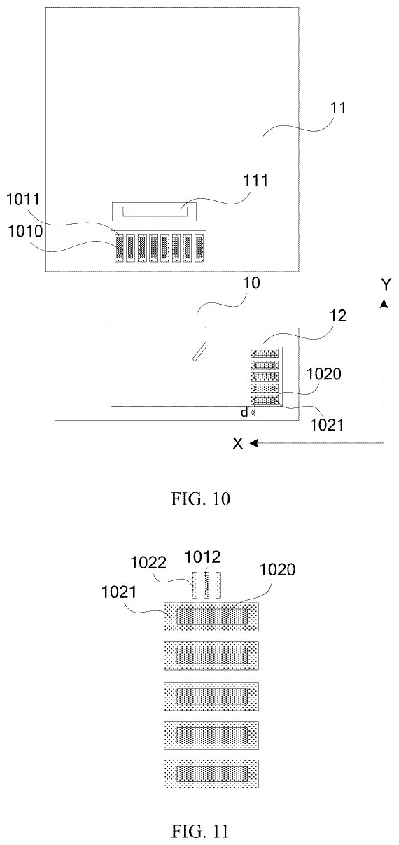

As another optional implementation of the disclosed content of the present disclosure, an embodiment of the present disclosure further discloses a display device, and the display device may be a flexible display device. FIG. 10 is a schematic structural diagram of a display device according to an embodiment of the present disclosure. As shown in FIG. 10, the display device includes a display panel 11, a printed circuit board 12, and a flexible printed circuit 10. Therein, the display panel 11 may be a flexible display panel. The flexible printed circuit 10 may be a flexible printed circuit according to any one disclosed in the embodiments mentioned above. The printed circuit board 12 may be a main board matched with the display panel 11.

In some embodiments of the present disclosure, as shown in FIG. 10, the display panel 11 includes a plurality of third connection terminals 1011. The plurality of third connection terminals 1011 are arranged in sequence along the first direction X, and are electrically connected to a plurality of first connection terminals 1010 respectively. In some embodiments, the display panel 11 may further include a driving chip 111 located in a non-display region. The plurality of third connection terminals 1011 are electrically connected to the driving chip 111 through wiring or other means to transmit a signal output by the flexible printed circuit 10 to the driving chip 111. Sub-pixels in a display region of the display panel 11 are controlled for image display through the driving chip 111. Therein, the non-display region at least partially surrounds the display region.

The printed circuit board 12 may include a plurality of fourth connection terminals 1021, and the plurality of fourth connection terminals 1021 are arranged in sequence along the second direction Y. The plurality of fourth connection terminals 1021 are electrically connected to a plurality of second connection terminals 1020 respectively. The plurality of fourth connection terminals 1021 are electrically connected to an electronic component or a power input/output port on the printed circuit board 12 to transmit a signal, input from an external to the printed circuit board 12, to the flexible printed circuit 10. And the signal may be transmitted to the display panel 11 through the flexible printed circuit 10.

After receiving the signal output from the printed circuit board 12, the plurality of second connection terminals 1020 on the flexible printed circuit 10 will transmit the signal to the plurality of first connection terminals 1010 through wiring or an electronic component disposed on the flexible printed circuit 10. And then, the signal may be transmitted to the display panel 11 through the plurality of first connection terminals 1010 and the plurality of third connection terminals 1011 to control displaying of the display panel 11.

The present disclosure is not limited to this, in other embodiments, the driving chip 111 may also be provided on the flexible printed circuit 10. An electrical signal of the printed circuit board 12 may be transmitted to the driving chip 111 by the plurality of second connection terminals 1020 and the plurality of fourth connection terminals 1021. After the driving chip 111 processes the electrical signal, the electrical signal may be transmitted to at least one of the plurality of first connection terminals 1010 corresponding to at least one of the plurality of second connection terminals 1020, and further transmitted to the display panel 11 through the first connection terminal 1010 and the third connection terminal 1011.

In some embodiments of the present disclosure, an extension direction of the plurality of third connection terminals 1011 is the same as an extension direction of the plurality of first connection terminals 1010, and an extension direction of the plurality of fourth connection terminals 1021 is the same as an extension direction of the plurality of second connection terminals 1020. The present disclosure is not limited to this, in other embodiments, the extension direction of the plurality of third connection terminals 1011 may be different from the extension direction of the plurality of first connection terminals 1010. For example, the extension direction of the plurality of third connection terminals 1011 may intersect with the extension direction of the plurality of first connection terminals 1010. The extension direction of the plurality of fourth connection terminals 1021 may also be different from the extension direction of the plurality of second connection terminals 1020. For example, the extension direction of the plurality of fourth connection terminals 1021 may intersect with the two intersect the extension direction of the plurality of second connection terminals 1020.

In some embodiments of the present disclosure, an orthographic projection of the third connection terminal 1011 on the display panel 11 covers an orthographic projection of the first connection terminal 1010 on the display panel 11, and an orthographic projection of the fourth connection terminal 1021 on the printed circuit board 12 covers an orthographic projection of the second connection terminal 1020 on the printed circuit board 12, thereby improving bonding accuracy between the third connection terminal 1011 and the first connection terminal 1010, and bonding accuracy between the fourth connection terminal 1021 and the second connection terminal 1020.

In some embodiments, as shown in FIG. 10, a length of the second connection terminal 1020 along the extension direction of the second connection terminal 1020 is less than a length of the fourth connection terminal 1021 along the extension direction of the fourth connection terminal 1021. Preferably, a distance d between an end face of the second connection terminal 1020 along the extension direction of the second connection terminal 1020 and an end face of a same side of the fourth connection terminal 1021 along the extension direction of the fourth connection terminal 1021 is less than 0.5 mm, so that when the flexible printed circuit 10 is made deviate in the second direction Y by the display panel 11, it may be still ensured that the orthographic projection of the fourth connection terminal 1021 on the printed circuit board 12 covers the orthographic projection of the second connection terminal 1020 on the printed circuit board 12, thereby ensuring alignment accuracy between the second connection terminal 1020 and the fourth connection terminal 1021.

In some embodiments of the present disclosure, as shown in FIG. 11, FIG. 11 is a schematic structural diagram of a plurality of second alignment marks according to an embodiment of the present disclosure. The flexible printed circuit 10 includes at least one first alignment mark 1012, and the printed circuit board 12 includes a plurality of second alignment marks 1022, so that alignment between the fourth connection terminal 1021 and the second connection terminal 1020 may be realized through the at least one first alignment mark 1012 and the plurality of second alignment marks 1022. At least one second alignment mark 1022 of the plurality of second alignment marks 1022 is configured for alignment between the plurality of fourth connection terminals 1021 and the plurality of second connection terminals 1020 in an offset state, and at least one second alignment mark 1022 of the plurality of second alignment marks 1022 is configured for alignment between the plurality of fourth connection terminals 1021 and the plurality of second connection terminals 1020 in a non-offset state. Moreover, the plurality of second alignment marks 1022 may correspond to alignment between the plurality of fourth connection terminals 1021 and the plurality of second connection terminals 1020 in different offset states.

The flexible printed circuit 10 may further include at least one third alignment mark, and the display panel 11 may further include a plurality of fourth alignment marks, so that alignment between the third connection terminal 1011 and the first connection terminal 1010 may be realized through the at least one third alignment mark and the plurality of fourth alignment marks. At least one fourth alignment mark of the plurality of fourth alignment marks is configured for alignment between the plurality of third connection terminals 1011 and the plurality of first connection terminals 1010 in a non-contracted state, and at least one fourth alignment mark of the plurality of fourth alignment marks is configured for alignment between the plurality of third connection terminals 1011 and the plurality of first connection terminals 1010 in a contracted state. Moreover, the plurality of fourth alignment marks may correspond to the alignment between the plurality of third connection terminals 1011 and the plurality of first connection terminals 1010 in different contracted states.

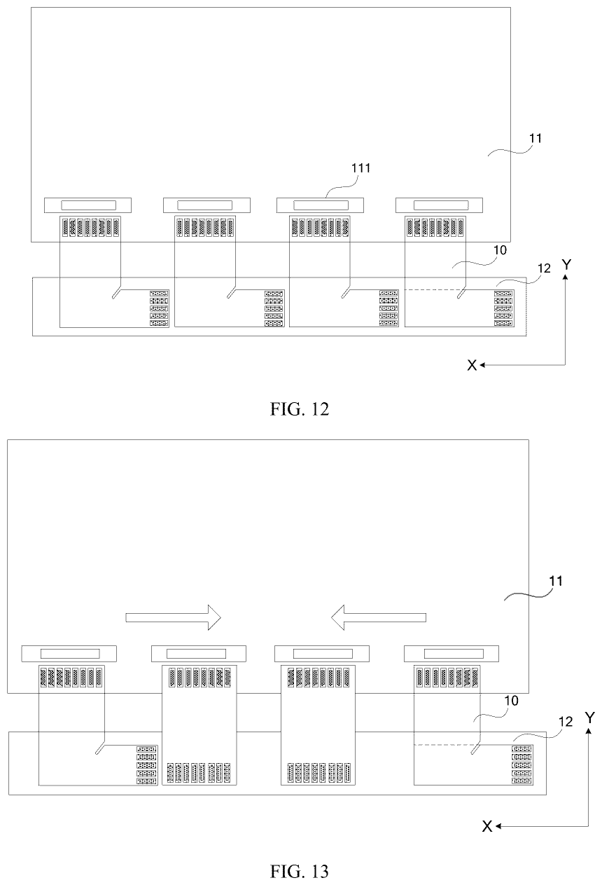

In some embodiments of the present disclosure, as shown in FIG. 12, FIG. 12 is a schematic structural diagram of another display device according to an embodiment of the present disclosure. The display panel 11 may include a plurality of bonding regions arranged in sequence along the first direction X. Each of the plurality of bonding regions corresponds to a driving chip 111, and each of the plurality of bonding regions is provided with a plurality of third connection terminals 1011. The display device includes a plurality of flexible printed circuits 10. A plurality of first connection terminals 1010 of each of the plurality of flexible printed circuits 10 are electrically connected to a plurality of third connection terminals 1011 in each of the plurality of bonding regions respectively. Based on this, the plurality of flexible printed circuits 10 are independent of each other, so that deviation of any one of the flexible printed circuits 10 will not accumulate on other flexible printed circuits 10. In other words, any one of the flexible printed circuits 10 will not cause other flexible printed circuits 10 to deviate, thereby reducing misalignment between the first connection terminal 1010 of the flexible printed circuit 10 and the third connection terminal 1011 of the display panel 11 in the first direction X.

The present disclosure is not limited to this. In other embodiments, as shown in FIG. 13, FIG. 13 is a schematic structural diagram of another display device according to an embodiment of the present disclosure. In a case where two sides of the display panel 11 contract towards the middle, or in other words, when contraction of the two sides of the display panel 11 is much greater than contraction of the middle of the display panel 11, the flexible printed circuit 10 disclosed in the embodiment of the present disclosure may only be bonded to the bonding regions located on two sides of the display panel 11. That is, the plurality of first connection terminals 1010 of two flexible printed circuits 10 are electrically connected to the plurality of third connection terminals 1011 in the bonding regions located on two sides of the display panel 11 in the first direction X respectively.

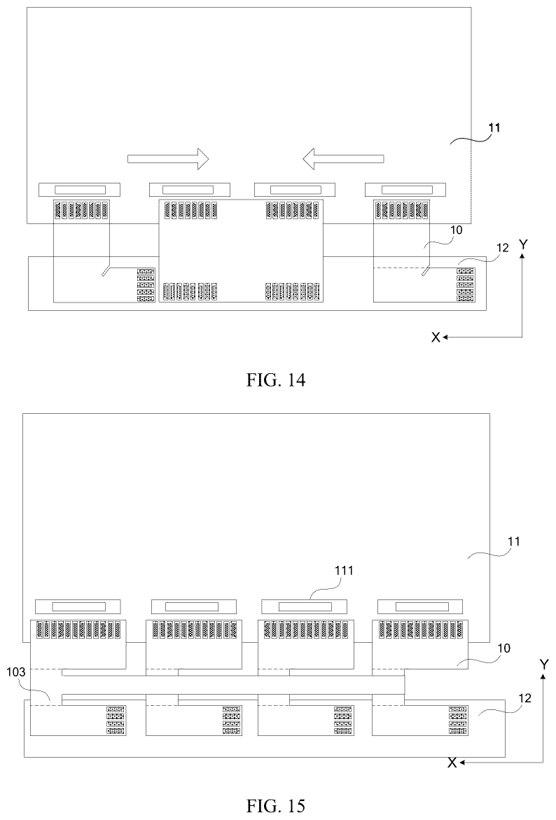

In some embodiments of the present disclosure, as shown in FIG. 13, the plurality of bonding regions located in the middle of the display panel 11 may be bonded to a plurality of flexible printed circuits 10 respectively. FIG. 14 is a schematic structural diagram of another display device according to an embodiment of the present disclosure. As shown in FIG. 14, the plurality of bonding regions located in the middle of the display panel 11 may also be bonded to a flexible printed circuit 10, which is not described herein again. In addition, in other embodiments, the plurality of flexible printed circuits 10 may also be connected to each other. FIG. 15 is a schematic structural diagram of another display device according to an embodiment of the present disclosure. As shown in FIG. 15, bending portions 103 of the plurality of flexible printed circuits 10 may be connected to each other, which is not described herein again.

In some embodiments of the present disclosure, as shown in FIG. 8, a plurality of first connection terminals 1010 may be located on a first side of the flexible printed circuit 13, and a plurality of second connection terminals 1020 may be located on a second side of the flexible printed circuit 10. The first side is opposite to the second side. Moreover, as shown in FIG. 9, the printed circuit board 12 includes a first surface and a second surface. The first surface is configured to arrange an electronic component, and the second surface is configured to arrange a plurality of fourth connection terminals 1021. The first surface is opposite to the second surface, so that the fourth connection terminals 1021 may not affect layout of the electronic component on the printed circuit board 12.

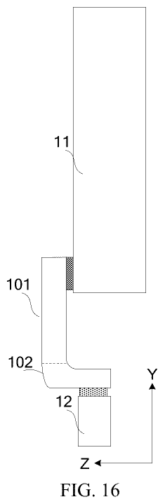

The present disclosure is not limited to this. In other embodiments, FIG. 16 is a schematic structural diagram of another display device according to an embodiment of the present disclosure. As shown in FIG. 16, the first surface may intersect with the second surface. That is to say, the plurality of fourth connection terminals 1021 may be arranged on a sidewall of the printed circuit board 12, so that the fourth connection terminals 1021 may not affect the layout of the electronic component on the printed circuit board 12.

The technical features of the embodiments mentioned above may be freely combined in any manner. To make the description brevity, not all possible combinations of the technical features in the above embodiments have been described. However, any combination of these technical features should be considered as falling within the scope of this specification, as long as there is no contradiction in such a combination.

The above embodiments merely represent several implementation modes of this specification, which are described in a relatively specific and detailed manner. However, this should not be construed as limiting the scope of the present disclosure. It should be noted that, for those skilled in the art, without deviating from the concept of this specification, numerous variations and improvements can still be made, all of which belong to the protection scope of this specification. Therefore, the protection scope of the present disclosure should be determined by the appended claims.

What is claimed is:

1. A flexible printed circuit, comprising a first main portion and a second main portion connected mutually,
wherein the first main portion is provided with a plurality of first connection terminals; the plurality of first connection terminals are arranged in sequence along a first direction; and the plurality of first connection terminals are configured to be electrically connected to a display panel; and
the second main portion is provided with a plurality of second connection terminals; the plurality of second connection terminals are arranged in sequence along a second direction; the plurality of second connection terminals are configured to be electrically connected to a printed circuit board; and the first direction intersects with the second direction.

2. The flexible printed circuit according to claim 1, wherein the first main portion comprises a strip-shaped structure extending along the second direction, the second main portion comprises a strip-shaped structure extending along the first direction;
the first direction is perpendicular to the second direction, and the first main portion and the second main portion form an L-shaped structure.

3. The flexible printed circuit according to claim 1, wherein an extension direction of the first main portion is parallel to an extension direction of the second main portion, and the flexible printed circuit comprising the first main portion and the second main portion is a U-shaped structure; or
the first main portion and the second main portion are triangular structures, and the flexible printed circuit comprising the first main portion and the second main portion is a triangular structure.

4. The flexible printed circuit according to claim 1, wherein the plurality of first connection terminals extend along a third direction, the third direction intersects with the first direction, the plurality of second connection terminals extend along a fourth direction, and the fourth direction intersects with the second direction.

5. The flexible printed circuit according to claim 4, wherein the third direction is parallel to the second direction, and the fourth direction is parallel to the first direction.

6. The flexible printed circuit according to claim 1, wherein the flexible printed circuit comprises at least one slot, the at least one slot extends from a junction of the first main portion and the second main portion to an interior of the flexible printed circuit.

7. The flexible printed circuit according to claim 6, further comprising a bending portion connected between the first main portion and the second main portion, wherein hardness of the bending portion is less than hardness of each of the first main portion and the second main portion.

8. The flexible printed circuit according to claim 1, wherein an electrical signal is transmitted from one of the plurality of second connection terminals to one of the plurality of first connection terminals corresponding to the second connection terminal.

9. The flexible printed circuit according to claim 8, wherein the plurality of first connection terminals are provided on a first side of the flexible printed circuit, the plurality of second connection terminals are provided on a second side of the flexible printed circuit, and the first side is opposite to the second side.

10. The flexible printed circuit according to claim 1, further comprising a driving chip, wherein
at least one of the plurality of second connection terminals is configured to transmit an electrical signal to the driving chip, and the driving chip is configured to process and transmit the electrical signal to at least one of the plurality of first connection terminals corresponding to the at least one of the plurality of second connection terminals.

11. A display device, comprising a display panel, a printed circuit board, and the flexible printed circuit according to claim 1.

12. The display device according to claim 11, wherein the display panel comprises a plurality of third connection terminals arranged in sequence along the first direction, and the plurality of third connection terminals are electrically connected to the plurality of first connection terminals respectively; and
the printed circuit board comprises a plurality of fourth connection terminals arranged in sequence along the second direction, and the plurality of fourth connection terminals are electrically connected to the plurality of second connection terminals respectively.

13. The display device according to claim 12, wherein a length of the second connection terminal in an extension direction of the second connection terminal is less than a length of the fourth connection terminal in an extension direction of the fourth connection terminal, and a distance between an end face of the second connection terminal in the extension direction of the second connection terminal and an end face of the fourth connection terminal, at a same side as the end face of the second connection terminal, in the extension direction of the fourth connection terminal is less than 0.5 mm.

14. The display device according to claim 12, wherein the display panel comprises a plurality of bonding regions arranged in sequence along the first direction, the plurality of third connection terminals are disposed within each of the plurality of bonding regions; and
the display device comprises a plurality of flexible printed circuits, the plurality of first connection terminals of each of the plurality of flexible printed circuits are electrically connected to the plurality of third connection terminals located in each of the plurality of bonding regions respectively; or the plurality of first connection terminals of two flexible printed circuits are respectively electrically connected to the plurality of third connection terminals located in bonding regions at both sides of the display panel in the first direction.

15. The display device according to claim 14, wherein the flexible printed circuit comprises at least one first alignment mark, the printed circuit board comprises a plurality of second alignment marks, at least one second alignment mark of the plurality of second alignment marks is configured for alignment between the plurality of fourth connection terminals and the plurality of second connection terminals in an offset state, and at least one second alignment mark is configured for alignment between the plurality of fourth connection terminals and the plurality of second connection terminals in a non-offset state.

16. The display device according to claim 14, wherein the flexible printed circuit further comprises at least one third alignment mark, the display panel further comprises a plurality of fourth alignment marks, at least one fourth alignment mark of the plurality of fourth alignment marks is configured for alignment between the plurality of third connection terminals and the plurality of first connection terminals in a non-contracted state, and at least one fourth alignment mark is configured for alignment between the plurality of third connection terminals and the plurality of first connection terminals in a contracted state.

17. The display device according to claim 11, wherein the printed circuit board comprises a first surface and a second surface, the first surface is configured to arrange an electronic component, the second surface is configured to arrange the plurality of fourth connection terminals, and the first surface intersects with the second surface or the first surface is opposite to the second surface.

18. The display device according to claim 11, wherein the display panel further comprises a driving chip, the driving chip is configured to receive an electrical signal transmitted from the printed circuit board through the plurality of first connection terminals, and process and transmit the electrical signal to the display panel.

19. The display device according to claim 12, wherein an orthographic projection of the third connection terminal on the display panel covers an orthographic projection of the first connection terminal on the display panel, and an orthographic projection of the fourth connection terminal on the printed circuit board covers an orthographic projection of the second connection terminal on the printed circuit board.

20. The display device according to claim 14, wherein each of the plurality of flexible printed circuits further comprises a bending portion connected between the first main portion and the second main portion, and the bending portions of adjacent flexible printed circuits are electrically connected to each other.
